(19) United States
(12) Patent Application Publication
(10) Pub. No.: US 2022/0001644 A1
(43) Pub. Date: Jan. 6, 2022

(54) STRUCTURED FILM AND ARTICLES THEREOF

(71) Applicant: 3M INNOVATIVE PROPERTIES COMPANY, St. Paul, MN (US)

(72) Inventors: David J. Rowe, Roseville, MN (US); Kevin W. Gotrik, Hudson, WI (US); Christopher S. Lyons, St. Paul, MN (US); Christopher A. Merton, St. Louis Park, MN (US); Scott J. Jones, Woodbury, MN (US); Ta-Hua Yu, Woodbury, MN (US); Brett J. Sitter, Cottage Grove, MN (US); John P. Baetzold, North St. Paul, MN (US); Bill H. Dodge, Finlayson, MN (US); Evan L. Schwartz, Vadnais Heights, MN (US)

(21) Appl. No.: 16/625,544

(22) PCT Filed: Jun. 14, 2018
(86) PCT No.: PCT/IB2018/054396

§ 371 Date: Dec. 20, 2019

Related U.S. Application Data
(60) Provisional application No. 62/525,040, filed on Jun. 26, 2017.

(51) Int. Cl. B32B 3/30; B32B 27/08; B32B 27/30; B32B 27/36; C23C 14/00; C23C 14/08; C23C 14/12; C23C 14/24; C23C 14/58; C23C 14/34; C23C 16/40; C23C 16/455; C09J 7/29; H01L 51/52

(52) U.S. Cl. CPC B32B 3/30; B32B 2405/00; B32B 27/308; B32B 27/36; C23C 14/0036; C23C 14/081; C23C 14/12; C23C 14/24; C23C 14/5846; C23C 14/3464; C23C 16/401; C23C 16/403; C23C 16/45555; C09J 7/29; H01L 51/5253; B32B 2250/02; B32B 2250/24; B32B 2255/26; B32B 2307/418; B32B 2307/7244; B32B 2307/7246; B32B 2457/206; B32B 2255/20; B32B 2255/28; B32B 27/08

(57) ABSTRACT

A film including: a substrate; a first barrier layer on the substrate; a first resin layer on the first barrier layer; wherein the first resin layer includes a structured major surface and a plurality of features; a second barrier layer on the structured major surface of the first resin layer; and a second resin layer on the second barrier layer, wherein the second resin layer includes a structured major surface and a plurality of features.

### BACKGROUND

Many electronic devices are sensitive to environmental gases and liquids and are prone to degradation upon permeation of the environmental gases and liquids such as oxygen and water vapor. Barrier films have been used for electrical, packaging and decorative applications to prevent the degradation. For example, multilayer stacks of inorganic or hybrid inorganic/organic layers can be used to make barrier films resistant to moisture permeation. Multilayer barrier films have also been developed to protect sensitive materials from damage due to water vapor. The water sensitive materials can be electronic components such as organic, inorganic, and hybrid organic/inorganic semiconductor devices. While the technology of the prior art may be useful, there exists a need for better barrier films useful for packaging electronic components.

### SUMMARY

In one aspect, the present disclosure provides a film comprising: a substrate; a first barrier layer on the substrate; a first resin layer on the first barrier layer; wherein the first resin layer comprises a structured major surface and a plurality of features; a second barrier layer on the structured major surface of the first resin layer; and a second resin layer on the second barrier layer, wherein the second resin layer comprises a structured major surface and a plurality of features.

In another aspect, the present disclosure provides an article, comprising: the film of the present disclosure; and an oxygen or moisture sensitive device.

Various aspects and advantages of exemplary embodiments of the present disclosure have been summarized. The above Summary is not intended to describe each illustrated embodiment or every implementation of the present disclosure. Further features and advantages are disclosed in the embodiments that follow. The Drawings and the Detailed Description that follow more particularly exemplify certain embodiments using the principles disclosed herein.

### Definitions

For the following defined terms, these definitions shall be applied for the entire Specification, including the claims, unless a different definition is provided in the claims or elsewhere in the Specification based upon a specific reference to a modification of a term used in the following definitions:

The terms “about” or “approximately” with reference to a numerical value or a shape means +/−five percent of the numerical value or property or characteristic, but also expressly includes any narrow range within the +/−five percent of the numerical value or property or characteristic as well as the exact numerical value. For example, a temperature of “about” 100° C. refers to a temperature from 95° C. to 105° C., but also expressly includes any narrower range of temperature or even a single temperature within that range, including, for example, a temperature of exactly 100° C. For example, a viscosity of “about” 1 Pa-sec refers to a viscosity from 0.95 to 1.05 Pa-sec, but also expressly includes a viscosity of exactly 1 Pa-sec. Similarly, a perimeter that is “substantially square” is intended to describe a geometric shape having four lateral edges in which each lateral edge has a length which is from 95% to 105% of the length of any other lateral edge, but which also includes a geometric shape in which each lateral edge has exactly the same length.

The term “substantially” with reference to a property or characteristic means that the property or characteristic is exhibited to a greater extent than the opposite of that property or characteristic is exhibited. For example, a substrate that is “substantially” transparent refers to a substrate that transmits more radiation (e.g. visible light) than it fails to transmit (e.g. absorbs and reflects). Thus, a substrate that transmits more than 50% of the visible light incident upon its surface is substantially transparent, but a substrate that transmits 50% or less of the visible light incident upon its surface is not substantially transparent.

The terms “a”, “an”, and “the” include plural referents unless the content clearly dictates otherwise. Thus, for example, reference to a material containing “a compound” includes a mixture of two or more compounds.

### BRIEF DESCRIPTION OF THE DRAWINGS

The disclosure may be more completely understood in consideration of the following detailed description of various embodiments of the disclosure in connection with the accompanying figures, in which:

FIG. 1 is a schematic side view of one embodiment of a structured film.

FIG. 2 is a schematic top view of one embodiment of a structured film.

FIG. 3 is a schematic top view of one embodiment of a structured film.

While the above-identified drawings, which may not be drawn to scale, set forth various embodiments of the present disclosure, other embodiments are also contemplated, as noted in the Detailed Description. In all cases, this disclosure describes the presently disclosed invention by way of representation of exemplary embodiments and not by express limitations. It should be understood that numerous other modifications and embodiments can be devised by those skilled in the art, which fall within the scope and spirit of this disclosure.

### DETAILED DESCRIPTION

Before any embodiments of the present disclosure are explained in detail, it is understood that the invention is not limited in its application to the details of use, construction, and the arrangement of components set forth in the following description. The invention is capable of other embodiments and of being practiced or of being carried out in various ways that will become apparent to a person of ordinary skill in the art upon reading the present disclosure. Also, it is understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. It is understood that other embodiments may be utilized and structural or logical changes may be made without departing from the scope of the present disclosure.

As used in this Specification, the recitation of numerical ranges by endpoints includes all numbers subsumed within that range (e.g. 1 to 5 includes 1, 1.5, 2, 2.75, 3, 3.8, 4, and 5, and the like).

Any direction referred to herein, such as “top,” “bottom,” “left,” “right,” “upper,” “lower,” “above,” below,” and other directions and orientations are described herein for clarity in reference to the figures and are not to be limiting of an actual device or system or use of the device or system. Many of the devices, articles or systems described herein may be used in a number of directions and orientations.

Unless otherwise indicated, all numbers expressing quantities or ingredients, measurement of properties and so forth used in the Specification and embodiments are to be understood as being modified in all instances by the term “about.” Accordingly, unless indicated to the contrary, the numerical parameters set forth in the foregoing specification and attached listing of embodiments can vary depending upon the desired properties sought to be obtained by those skilled in the art utilizing the teachings of the present disclosure. At the very least, and not as an attempt to limit the application of the doctrine of equivalents to the scope of the claimed embodiments, each numerical parameter should at least be construed in light of the number of reported significant digits and by applying ordinary rounding techniques.

There is an increased need for barriers for electronic devices, which are sensitive to environmental gases and liquids, for example, organic light-emitting diode (OLED) device to reduce the amount of moisture and oxygen reaching the electronic devices. Typical approaches involve using a barrier film to prevent oxygen and moisture transport in the z direction. However, this does not help in the x and y direction because the adhesive used to attach the barrier film to the OLED provides a large channel for moisture ingress from the side of the device. The present application provides a film, which can prevent transportation of oxygen or moisture in the x and y direction.

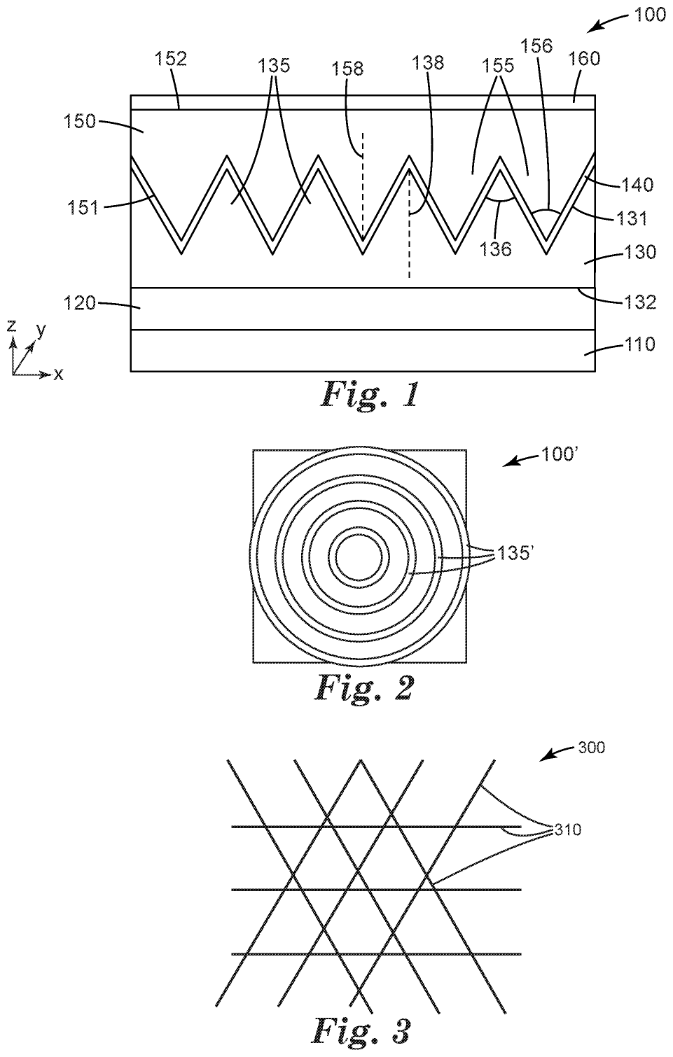

FIG. 1 is a schematic side view of one embodiment of film 100. The film 100 includes a substrate 110 and a first barrier layer 120 on the substrate 110. The film 100 may further include a first resin layer 130 on the first barrier layer 120. The first resin layer 130 includes a structured major surface 131 and a plurality of features 135. The first resin layer 130 includes a second major surface 132 that is opposite structured major surface 131. In some embodiments, the structured major surface 131 may include the plurality of features 135. Film 100 may also include a second barrier layer 140 on the structured major surface 131 of the first resin layer 130 and a second resin layer 150 on the second barrier layer 140. The second resin layer 150 has a first major surface 151 in contact with barrier layer 140 and a second major surface 152 opposite the first major surface 151. The second resin layer 150 may include a plurality of features 155. In some embodiments, the structured major surface 151 may include the plurality of features 155. In some embodiments, features 135 or 155 may be microscale features. In some embodiments, features 135 or 155 may be microreplicated features. In some embodiments, features 135 or 155 may be optical elements. In some embodiments, features 135 or 155 may be linear prisms as illustrated in FIG. 1. In some embodiments, film 100 may include an optional adhesive layer 160 on the second resin layer 150.

The plurality of features 135′ of the first resin layer may extend along concentric circles, as illustrated in FIG. 2, the schematic top view of one embodiment, or extend along concentric rectangles, squares, or other polygon shapes, not shown.

In some embodiments, the plurality of features 135 or 155 extend along a first direction, for example, y direction as illustrated in FIG. 1. In some of these embodiments, the plurality of features 135 or 155 may be substantially continuous along the first direction, for example, y direction as illustrated in FIG. 1. In some embodiments, the plurality of features 135 or 155 are substantially continuous along a second direction, for example, x direction as illustrated in FIG. 1. The plurality of features 135 or 155 of the embodiment of FIG. 1 extend along substantially same direction, the y direction. In some embodiments, the plurality of features extend along a parallel first direction, as illustrated in FIG. 1. In other embodiments, at least two of features of the first resin layer or the second resin layer extend along a non-parallel first direction, as illustrated in FIG. 3, a schematic top view of one embodiment of film 300. In FIG. 3, the plurality of features 310 of the first resin layer cross over with each other in the directions that features 310 extend along. In other embodiments, the plurality of features extend along concentric circles, concentric rectangles, squares, or other polygon shapes. In some embodiments, the plurality of features 135 or 155 exists within the light path of an optoelectronic device to a viewer. In some embodiments, more than 75% structured major surface 131 or 151 is the surface of the plurality of features 135 or 155. In some embodiments, a height of the plurality of features can be between 5 μm and 50 μm.

In general, features can be any type microscale or nanoscale structures. In some embodiments, the plurality of features may be randomly arrayed features. In some embodiments, the plurality of features may be randomly arrayed nanoscale features. In some embodiments, the plurality of features may be ordered features. In some embodiments, the plurality of features may include both microscale features and nanoscale features. In some embodiments, at least part of the nanoscale features may be formed on the microscale features. In some embodiments, the plurality of features may include both ordered microscale features and randomly arrayed nanoscale features.

In some embodiments, the nanoscale features have a high aspect ratio (the ratio of height to width). In some embodiments, aspect ratio (the ratio of height to width) of the nanoscale features is 1:1, 2:1, 4:1, 5:1, 8:1, 10:1, 50:1, 100:1, or 200:1. In some embodiments, aspect ratio (the ratio of height to width) of the nanoscale features can be more than 1:1, 2:1, 4:1, 5:1, 8:1, 10:1, 50:1, 100:1, or 200:1. Nanoscale features can be such as, for example, nano-pillars or nano-columns, or continuous nano-walls: comprising nano-pillars or nano-columns. In some embodiments, the nanoscale features have steep side walls that are substantially perpendicular to the substrate. In some embodiments, the majority of the nanoscale features can be capped with mask material.

The structured surface with nanoscale features can exhibit one or more desirable properties such as antireflective properties, light absorbing properties, antifogging properties, improved adhesion and durability. For example, in some embodiments, the structured surface reflectivity of electromagnetic energy is about 50% or less than the surface reflectivity of an untreated surface in an energy range of interest (e.g. visible light, IR, UV, etc.). As used herein with respect to comparison of surface properties, the term “untreated surface” means the surface of an article comprising the same matrix material and the same nanodispersed phase (as the nanostructured surface of the invention to which it is being compared) but without a nanoscale features. In some embodiments, the percent reflection of the structured surface with nanoscale features can be less than about 2% (typically, less than about 1%) as measured using the “Measurement of Average % Reflection” method described in U.S. Pat. No. 8,634,146 (David et al.). Likewise, in some embodiments, the percent electromagnetic energy transmission of the structured surface with nanoscale features of an energy range of interest can be about 2% or more than the percent transmission of an untreated surface as measured using the “Measurement of Average % Transmission” method described in U.S. Pat. No. 8,634,146 David et al.).

In some embodiments, the nanoscale features are closely spaced, for example, the space between adjacent nanoscale features being less than 100 nm. In some embodiments, the space between adjacent nanoscale features can be less than the width of the nanoscale features. In some embodiments, the nanoscale features may include vertical or near-vertical sidewalls.

In other embodiments, the nanostructured anisotropic surface can have a water contact angle of less than about 20°, less than about 15°, or even less than about 10° as measured using the “Water Contact Angle Measurement” method described in the Example section below. In still other embodiments, the nanostructured anisotropic surface can absorb about 2% or more light than an untreated surface. In yet other embodiments of the invention, the nanostructured anisotropic surface can have a pencil hardness greater than about 2H (typically, greater than about 4H) as determined according to ASTM D-3363-05. In other embodiments, an article is provided that can be made in a continuous manner by the provided method so that the percentage of light (measured at 450 nm) transmitted through the localized nanostructured surface that is deflected more than 2.5 degrees from the direction of incoming beam is less than 2.0%, typically less than 1.0%, and more typically less than 0.5%.

In the exemplary structured film 100, features 135 or 155 may be prismatic linear structures. In some embodiments, the cross-sectional profiles of features 135 or 155 can be or include curved and/or piece-wise linear portions. For example, in some cases, features can be linear cylindrical lenses extending along the y-direction. Each feature 135 or 155 includes an apex angle 136 or 156 and a height 138 or 158 measured from a common reference plane such as, for example, second major surface 132 or 152. In the exemplary structured film 100, height 138 or 158 are substantially same along the x-direction. In some other embodiments, the height 138 or 158 can vary along the x-direction. For example, some of the linear features 135 or 155 are shorter and some of the linear features 135 or 155 are taller. In some embodiments, height 138 or 158 may be substantially same along the y-direction. For example, a prismatic linear feature 135 or 155 may have a constant height along the y-direction. In some other embodiments, the height 138 or 158 may change along the y-direction. For example, the height 138 or 158 varies along the y-direction. In such cases, features 135 or 155 may have a local height that varies along the y-direction, a maximum height, and an average height. In some embodiments, the height 138 or 158 can be between 5 μm and 50 μm.

Apex or dihedral angle 136 or 156 can have any value that may be desirable in an application. For example, in some embodiments, apex angle 136 or 156 can be in a range from about 70 degrees to about 120 degrees, or from about 80 degrees to about 100 degrees, or from about 85 degrees to about 95 degrees. In some embodiments, features 135 or 155 have equal apex angles which can, for example, be in a range from about 88 or 89 degrees to about 92 or 91 degrees, such as 90 degrees.

The first or second resin layer can have any index of refraction that may be desirable in an application. For example, in some cases, the index of refraction of the first or second resin layer is in a range from about 1.4 to about 1.8, or from about 1.5 to about 1.8, or from about 1.5 to about 1.7. In some cases, the index of refraction of the first or second resin layer is not less than about 1.4, not less than about 1.5, or not less than about 1.55, or not less than about 1.6, or not less than about 1.65, or not less than about 1.7. The adhesive layer can have any index of refraction that may be desirable in an application. In some embodiments, the first or second resin layer has a first refractive index, the adhesive layer has a second refractive index and the second refractive index is different from the first refractive index. In other embodiments, the second refractive index is substantially the same as the first refractive index so that the first or second resin layer and the adhesive layer are index matched.

The first or second resin layer may include a crosslinked or soluble resin. Suitable crosslinked or soluble resin include those described in U.S. Pat. App. Pub. No. 2016/0016338 (Radcliffe et al.), for example, UV-curable acrylates, such as polymethyl methacrylate (PMMA), aliphatic urethane diacrylates (such as Photomer 6210, available from Sartomer Americas, Exton, Pa.), epoxy acrylates (such as CN-120, also available from Sartomer Americas), and phenoxyethyl acrylate (available from Sigma-Aldrich Chemical Company, Milwaukee, Wis.). Other suitable curable resins include moisture cured resins such as Primer M available from MAPEI Americas (Deerfield Beach, Fla.). Additional suitable viscoelastic or elastomeric adhesives and additional suitable crosslinkable resins are described in U.S. Pat. App. Pub. No. 2013/0011608 (Wolk et al.). As used herein, a “soluble resin” is a resin having the material property that it is soluble in a solvent that is suitable for use in a web coating process. In some embodiments, soluble resins are soluble to at least 3 weight percent, or at least 5 weight percent, or at least 10 weight percent or at least 20 weight percent or at least 50 weight percent at 25.degree. C. in at least one of methyl ethyl ketone (MEK), toluene, ethyl acetate, acetone, methanol, ethanol, isopropanol, 1,3 dioxolane, tetrahydrofuran (THF), water and combinations thereof. A soluble resin layer may be formed by coating a solvent-borne soluble resin and evaporating the solvent. Soluble resin layers may have low or substantially no birefringence. Suitable soluble resins include VITEL 1200B available from Bostik, Inc. (Wauwatosa, Wis.), PRIPOL 1006 available from Croda USA (New Castle, Del.), and soluble aziridine resins as described, for example, in U.S. Pat. No. 5,534,391 (Wang). Structured resin layer with features prepared according to a process as described, for example, in U.S. Pat. No. 5,175,030 (Lu et al.); U.S. Pat. No. 5,183,597 (Lu); U.S. Pat. App. Pub. No. 2016/0016338 (Radcliffe et al.); U.S. Pat. App. Pub. No. 2016/0025919 (Boyd) by a tool fabricated using a diamond turning method that utilized a fast tool servo (FTS) as described, for example, in PCT Published Application No. WO 00/48037 (Campbell et al.), and U.S. Pat. No. 7,350,442 (Ehnes et al.) and U.S. Pat. No. 7,328,638 (Gardiner et al.). Microscale or nanoscale structures can be formed by the method described in U.S. Pat. No. 8,634,146 (David et al.).

The first or second barrier layer may include an inorganic barrier layer and a first crosslinked polymer layer. In some embodiments, the first or second barrier layer further comprises a second crosslinked polymer layer, and the inorganic barrier layer is sandwiched by the first and second crosslinked polymer layers.

The inorganic barrier layer can be formed from a variety of materials including, for example, metals, metal oxides, metal nitrides, metal carbides, metal oxynitrides, metal oxyborides, and combinations thereof. Exemplary metal oxides include silicon oxides such as silica, aluminum oxides such as alumina, titanium oxides such as titania, indium oxides, tin oxides, indium tin oxide (ITO), tantalum oxide, zirconium oxide, niobium oxide, and combinations thereof. Other exemplary materials include boron carbide, tungsten carbide, silicon carbide, aluminum nitride, silicon nitride, boron nitride, aluminum oxynitride, silicon oxynitride, boron oxynitride, zirconium oxyboride, titanium oxyboride, and combinations thereof. In some embodiments, the inorganic barrier layer may include at least one of ITO, silicon oxide, or aluminum oxide. In some embodiments, the first or second polymer layer may be formed by applying a layer of a monomer or oligomer and crosslinking the layer to form the polymer in situ, for example, by evaporation and vapor deposition of a radiation-crosslinkable monomer cured by, for example, using an electron beam apparatus, UV light source, electrical discharge apparatus or other suitable device.

The first or second barrier layer may include at least one selected from the group consisting of individual metals, two or more metals as mixtures, inter-metallics or alloys, metal oxides, metal and mixed metal oxides, metal and mixed metal fluorides, metal and mixed metal nitrides, metal and mixed metal carbides, metal and mixed metal carbonitrides, metal and mixed metal oxynitrides, metal and mixed metal borides, metal and mixed metal oxy borides, metal and mixed metal silicides; diamond-like materials including dopants such as Si, O, N, F, or methyl groups; amorphous or tetrahedral carbon structures, amorphous or tetrahedral carbon structures including H or N, graphene, graphene oxide, and combinations thereof. In some embodiments, the first or second barrier layer may conveniently be formed of metal oxides, metal nitrides, metal oxy-nitrides, and metal alloys of oxides, nitrides and oxy-nitrides. In one aspect, the first or second barrier layer may include a metal oxide. In some embodiments, the barrier layer 150 may include at least one the metal oxides or metal nitrides selected from the group of silicon oxides, aluminum oxides, titanium oxides, indium oxides, tin oxides, indium tin oxide (ITO), hafnium oxide, tantalum oxide, zirconium oxide, zinc oxide, niobium oxide, silicon nitrides, aluminum nitrides, and combinations thereof. The first or second barrier layer can typically be prepared by reactive evaporation, reactive sputtering, chemical vapor deposition, plasma enhanced chemical vapor deposition, and atomic layer deposition. Preferred methods include vacuum preparations such as reactive sputtering and plasma enhanced chemical vapor deposition, and atomic layer deposition.

The adhesive layer can include a viscoelastic or elastomeric adhesive. Viscoelastic or elastomeric adhesives can include those described in U.S. Pat. App. Pub. No. 2016/0016338 (Radcliffe et al.), for example, pressure-sensitive adhesives (PSAs), rubber-based adhesives (e.g., rubber, urethane) and silicone-based adhesives. Viscoelastic or elastomeric adhesives also include heat-activated adhesives which are non-tacky at room temperature but become temporarily tacky and are capable of bonding to a substrate at elevated temperatures. Heat activated adhesives are activated at an activation temperature and above this temperature have similar viscoelastic characteristics as PSAs. Viscoelastic or elastomeric adhesives may be substantially transparent and optically clear. Any of the viscoelastic or elastomeric adhesives of the present description may be viscoelastic optically clear adhesives. Elastomeric materials may have an elongation at break of greater than about 20 percent, or greater than about 50 percent, or greater than about 100 percent. Viscoelastic or elastomeric adhesive layers may be applied directly as a substantially 100 percent solids adhesive or may be formed by coating a solvent-borne adhesive and evaporating the solvent. Viscoelastic or elastomeric adhesives may be hot melt adhesives which may be melted, applied in the melted form and then cooled to form a viscoelastic or elastomeric adhesive layer. Suitable viscoelastic or elastomeric adhesives include elastomeric polyurethane or silicone adhesives and the viscoelastic optically clear adhesives CEF22, 817x, and 818x, all available from 3M Company, St. Paul, Minn. Other useful viscoelastic or elastomeric adhesives include PSAs based on styrene block copolymers, (meth)acrylic block copolymers, polyvinyl ethers, polyolefins, and poly(meth)acrylates. The first or second adhesive layer 160 or 180 can include a UV cured adhesive.

Substrate may include any of a wide variety of non-polymeric materials, such as glass, or various thermoplastic and crosslinked polymeric materials, such as polyethylene terephthalate (PET), polyethylene naphthalate (PEN), (e.g. bisphenol A) polycarbonate, cellulose acetate, poly(methyl methacrylate), and polyolefins such as biaxially oriented polypropylene, cyclic olefin polymer (COP), and cyclic olefin copolymer (COP) which are commonly used in various optical devices. In some embodiments, the substrate may be a barrier film. In some embodiments, the substrate may be removable substrate.

In some embodiments, the films of the present disclosure can be used to prevent the moisture or oxygen spreading to an oxygen or moisture sensitive device. In some embodiments, an article can include the films of the present disclosure and an oxygen or moisture sensitive device. Suitable oxygen or moisture sensitive device, may include but not limited to, OLED devices, quantum dot, or photovoltaic devices and solar panels. The film of the present disclosure may provide barrier properties in both the x-y direction and the z direction. The barrier layer can conform to the shape of features and thus can prevent the moisture or oxygen spreading in x-y direction in addition to z direction. This could eliminate the need for an additional barrier film on top of the oxygen or moisture sensitive device. In addition, there is no need for sealing the edge of the device, since there are x-y direction barrier to prevent the moisture or oxygen spreading.

The following embodiments are intended to be illustrative of the present disclosure and not limiting.

### Embodiments

Embodiment 1 is a film comprising: a substrate; a first barrier layer on the substrate; a first resin layer on the first barrier layer; wherein the first resin layer comprises a structured major surface and a plurality of features; a second barrier layer on the structured major surface of the first resin layer; and a second resin layer on the second barrier layer, wherein the second resin layer comprises a structured major surface and a plurality of features.
Embodiment 2 is the film of embodiment 1, further comprising an adhesive layer on the second resin layer.
Embodiment 3 is the film of embodiment 2, wherein the first or second resin layer has a first refractive index, the adhesive layer has a second refractive index and the second refractive index is different from the first refractive index.
Embodiment 4 is the film of embodiment 2, wherein the first or second resin layer has a first refractive index, the adhesive layer has a second refractive index and the second refractive index is substantially the same as the first refractive index.
Embodiment 5 is the film of any one of embodiments 1 to 4, wherein the first resin layer comprises a second flat major surface opposite the structured major surface of the first resin layer.
Embodiment 6 is the film of any one of embodiments 1 to 5, wherein the second resin layer comprises a second flat major surface opposite the structured major surface of the second resin layer.
Embodiment 7 is the film of any one of embodiments 1 to 5, wherein a height of the plurality of features is between 5 μm and 50 μm.
Embodiment 8 is the film of any one of embodiments 1 to 7, wherein the plurality of features extend along a first direction.
Embodiment 9 is the film of any one of embodiments 1 to 7, wherein at least two of features extend along a non-parallel first direction.
Embodiment 10 is the film of any one of embodiments 1 to 9, wherein the plurality of features are substantially continuous along a second direction.
Embodiment 11 is the film of any one of embodiments 1 to 10, wherein the plurality of features are linear prisms extending along concentric circles, rectangles, squares, or other polygon shapes.
Embodiment 12 is the film of any one of embodiments 1 to 6 and 8 to 11, wherein the plurality of features are nanoscale features.
Embodiment 13 is the film of embodiment 12, wherein the plurality of features are randomly arrayed features.
Embodiment 14 is the film of embodiment 13, wherein the randomly arrayed features are randomly arrayed nanoscale features.
Embodiment 15 is the film of any one of embodiments 1 to 14, wherein the plurality of features are orderly arrayed features.
Embodiment 16 is the film of any one of embodiments 1 to 15, wherein the plurality of features comprise microscale features and nanoscale features.
Embodiment 17 is the film of embodiment 16, wherein the plurality of features comprise ordered microscale features and randomly arrayed nanoscale features.
Embodiment 18 is the film of embodiment 16, wherein the nanoscale features are formed on the microscale features.
Embodiment 19 is an article, comprising: the film of any one of embodiments 1 to 18; and an oxygen or moisture sensitive device.

### EXAMPLES

These Examples are merely for illustrative purposes and are not meant to be overly limiting on the scope of the appended claims. Notwithstanding that the numerical ranges and parameters setting forth the broad scope of the present disclosure are approximations, the numerical values set forth in the specific examples are reported as precisely as possible. Any numerical value, however, inherently contains certain errors necessarily resulting from the standard deviation found in their respective testing measurements. At the very least, and not as an attempt to limit the application of the doctrine of equivalents to the scope of the claims, each numerical parameter should at least be construed in light of the number of reported significant digits and by applying ordinary rounding techniques.

### Materials

Unless otherwise noted, all parts, percentages, ratios, etc. in the Examples and the rest of the specification are by weight. Solvents and other reagents used may be obtained from Sigma-Aldrich Chemical Company (Milwaukee, Wis.) unless otherwise noted. In addition, Table 1 provides abbreviations and a source for all materials used in the Examples.

TABLE 1
Materials.

| Tradename or | | |
|---|---|---|
| reference | Description | Source |
| SR833S | liquid tricyclodecane dimethanol | Sartomer USA, LLC, Exton, PA |
| | diacrylate | |
| Dynasylan 1189 | N-(n-butyl)-3- | Evonik, Essen, DE |
| | aminopropyltrimethoxysilane | |
| Irgacure 184 | 1-hydroxycyclohexyl phenyl ketone | BASF Corporation, Tarrytown, NY |
| Irgacure 1173 | 2-Hydroxy-2-methyl-1-phenyl-1- | BASF Corporation, Tarrytown, NY |
| | propanone | |
| 90%/10% wt % | Sputter targets | Soleras Advanced Coatings US, |
| silicon/aluminum | | Biddeford, ME |
| TMA | Trimethylaluminum | Strem Chemicals, Inc., Newburyport, |
| | | MA |
| SAM.24 | bis(diethylamino)silane | Air Liquide USA, Houston, TX |
| PIB | Polyisobutylene adhesive | BASF Corporation, Tarrytown, NY |
| CN120 | Epoxy acrylate | Sartomer USA, LLC, Exton, PA |
| PEA | 2-Phenoxyethyl acrylate | TCI America, Portland, OR |
| TPO | Diphenyl(2,4,6- | PL Industries, a division of Esstech, Inc., |
| | trimethylbenzoyl)phosphine oxide | Essington, PA |
| Melinex XST6692 PET | polyethylene terephthalate | Teijin DuPont Films, Chester, VA |
| Melinex 454 PET | polyethylene terephthalate | Teijin DuPont Films, Chester, VA |
| 3M PET | polyethylene terephthalate | 3M Corporation, St. Paul, MN |

### Comparative Example 1: Substrate/Sputtered Barrier

Comparative Example 1 was produced using a substrate of 5 mil (0.13 mm) thick PET film (Melinex XST 6692, Teijin DuPont Films, Chester, Va.). Additional samples of the Example 1 construction were also generated using a 5 mil (0.13 mm) thick PET produced by 3M. The sputtered barrier stack was prepared by coating the PET film described above with a stack of layers consisting of a base polymer (Layer 1), an inorganic silicon aluminum oxide (SiAlOx) barrier layer (Layer 2), and a protective polymeric layer (Layer 3) to produce a planar barrier-coated film. The three layers were coated in a vacuum coater like the coater described in U.S. Pat. No. 5,440,446 (Shaw, et al.) with the exception of using one or more sputtering sources instead of one evaporator source. The individual layers were formed as follows:

### Layer 1 (Base Polymer Layer)

The PET substrate film was loaded into a roll-to-roll vacuum processing chamber. The chamber was pumped down to a pressure of 2×10⁻⁵ Torr. A web speed of 4.9 meter/min was held while maintaining the backside of the film in contact with a coating drum chilled to −10° C. With the backside in contact with the drum, the film front-side surface was treated with a nitrogen plasma at 0.02 kW of plasma power. The film front-side surface was then coated with tricyclodecane dimethanol diacrylate monomer (obtained under the trade designation “SR833S”, from Sartomer USA, Exton, Pa.). The monomer was degassed under vacuum to a pressure of 20 mTorr prior to coating, combined with Irgacure 184 at a 95:5 wt % ratio of SR833S to Irgacure 184, loaded into a syringe pump, and pumped at a flow rate of 1.33 mL/min through an ultrasonic atomizer operating at a frequency of 60 kHz into a heated vaporization chamber maintained at 260° C. The resulting monomer vapor stream condensed onto the film surface and was crosslinked by exposure to ultra-violet radiation from mercury amalgam UV bulbs (Model MNIQ 150/54 XL, Heraeus, Newark N.J.) to form an approximately 750 nm thick base polymer layer.

### Layer 2 (Barrier Layer)

Immediately after the base polymer layer deposition and with the backside of the film still in contact with the drum, a SiAlOx layer was sputter-deposited atop the cured base polymer layer. An alternating current (AC) 60 kW power supply (obtained from Advanced Energy Industries, Inc., of Fort Collins, Colo.) was used to control a pair of rotatable cathodes housing two 90% Si/10% Al sputtering targets (obtained from Soleras Advanced Coatings US, of Biddeford, Me.). During sputter deposition, the oxygen flow rate signal from the gas mass flow controller was used as an input for a proportional-integral-differential control loop to maintain a predetermined power to the cathode. The sputtering conditions were: AC power 16 kW, 600 V, with a gas mixture containing 350 standard cubic centimeter per minute (sccm) argon and 190 sccm oxygen at a sputter pressure of 4.0 mTorr. This resulted in an 18-28 nm thick SiAlOx layer deposited atop the base polymer layer (Layer 1).

### Layer 3 (Protective Polymeric Layer) (Optional)

Immediately after the SiAlOx layer deposition and with the film still in contact with the drum, a second acrylate was coated and crosslinked using the same general conditions as for Layer 1, but the composition of this protective polymeric layer contained 3 wt. % of N-(n-butyl)-3-aminopropyltrimethoxysilane (obtained as DYNASYLAN 1189 from Evonik of Essen, Del.) and 5 wt. % Irgacure 184, with the remainder being Sartomer SR833S.

### Example 1: Substrate/Sputtered Barrier/Ordered Micro-Array/ALD Barrier/Resin Backfill Substrate

Example 1 was produced using a substrate of 5 mil (0.13 mm) thick PET film (Melinex XST 6692, Teijin DuPont Films, Chester, Va.). Additional samples of the Example 1 construction were also generated using a 5 mil (0.13 mm) thick PET produced by 3M.

### Sputtered Barrier

The sputtered barrier stack was prepared by coating the PET film described above with a stack of layers consisting of a base polymer (Layer 1), an inorganic silicon aluminum oxide (SiAlOx) barrier layer (Layer 2), and a protective polymeric layer (Layer 3) to produce a planar barrier-coated film. The three layers were coated in a vacuum coater like the coater described in U.S. Pat. No. 5,440,446 (Shaw, et al.) with the exception of using one or more sputtering sources instead of one evaporator source. The individual layers were formed as follows:

### Layer 1 (Base Polymer Layer)

The PET substrate film was loaded into a roll-to-roll vacuum processing chamber. The chamber was pumped down to a pressure of 2×10⁻⁵ Torr. A web speed of 4.9 meter/min was held while maintaining the backside of the film in contact with a coating drum chilled to −10° C. With the backside in contact with the drum, the film front-side surface was treated with a nitrogen plasma at 0.02 kW of plasma power. The film front-side surface was then coated with tricyclodecane dimethanol diacrylate monomer (obtained under the trade designation “SR833S”, from Sartomer USA, Exton, Pa.). The monomer was degassed under vacuum to a pressure of 20 mTorr prior to coating, combined with Irgacure 184 at a 95:5 wt % ratio of SR833S to Irgacure 184, loaded into a syringe pump, and pumped at a flow rate of 1.33 mL/min through an ultrasonic atomizer operating at a frequency of 60 kHz into a heated vaporization chamber maintained at 260° C. The resulting monomer vapor stream condensed onto the film surface and was crosslinked by exposure to ultra-violet radiation from mercury amalgam UV bulbs (Model MNIQ 150/54 XL, Heraeus, Newark N.J.) to form an approximately 750 nm thick base polymer layer.

### Layer 2 (Barrier Layer)

Immediately after the base polymer layer deposition and with the backside of the film still in contact with the drum, a SiAlOx layer was sputter-deposited atop the cured base polymer layer. An alternating current (AC) 60 kW power supply (obtained from Advanced Energy Industries, Inc., of Fort Collins, Colo.) was used to control a pair of rotatable cathodes housing two 90% Si/10% Al sputtering targets (obtained from Soleras Advanced Coatings US, of Biddeford, Me.). During sputter deposition, the oxygen flow rate signal from the gas mass flow controller was used as an input for a proportional-integral-differential control loop to maintain a predetermined power to the cathode. The sputtering conditions were: AC power 16 kW, 600 V, with a gas mixture containing 350 standard cubic centimeter per minute (sccm) argon and 190 sccm oxygen at a sputter pressure of 4.0 mTorr. This resulted in an 18-28 nm thick SiAlOx layer deposited atop the base polymer layer (Layer 1).

### Layer 3 (Protective Polymeric Layer) (Optional)

Immediately after the SiAlOx layer deposition and with the film still in contact with the drum, a second acrylate was coated and crosslinked using the same general conditions as for Layer 1, but the composition of this protective polymeric layer contained 3 wt. % of N-(n-butyl)-3-aminopropyltrimethoxysilane (obtained as DYNASYLAN 1189 from Evonik of Essen, Del.) and 5 wt. % Irgacure 184, with the remainder being Sartomer SR833S.

Optionally, the protective polymer layer was omitted but a liner was then placed on the barrier oxide surface in the vacuum coater, before the film was wound up into a roll.

### Ordered Micro-Array

An ordered micro-array was prepared over the top of the planar sputtered barrier stack using a tool that was fabricated using a diamond turning method as described in U.S. Pat. No. 5,696,627 (Benson et al.). The tool was used in a cast-and-cure process as described, for example, in U.S. Pat. No. 5,175,030 (Lu et al.) and U.S. Pat. No. 5,183,597 (Lu), to produce an ordered micro-array of sinusoidal features aligned in the x-y plane. An acrylate resin having a refractive index of 1.56 was used to form the microstructures. This acrylate resin was a polymerizable composition prepared by mixing CN120, PEA, Irgacure 1173, and TPO at a weight ratio of 75/25/0.25/0.1. The microstructures had a peak-to-valley height of 2.4 μm and a pitch (peak-to-peak or valley-to-valley distance) of 16 μm.

### ALD Barrier

A conformal barrier was prepared by means of atomic layer deposition (ALD) over the top of the ordered micro-array. The ALD barrier stack was prepared by coating the microstructured side of the ordered micro-array with an inorganic multilayer oxide. A homogenous silicon aluminum oxide (SiAlOx) was deposited by using a standard ALD chamber using bis(diethylamino)silane precursor (trade name SAM.24) at 40° C. and trimethylaluminum precursor (TMA) at 30° C., at a deposition temperature of 125° C. and at a deposition pressure approximately 1 Torr. The substrate was exposed to 80 total ALD cycles (mixture sequences). Each mixture sequence consists of a remote rf O₂ plasma powered at 300 W for 4 seconds, followed by a purging cycle, followed by a dose of TMA for 0.02 seconds, followed by a purging cycle, followed by a remote rf O₂ plasma powered at 300 W for 4 seconds, followed by a purging cycle, followed by a dose of SAM.24 for 0.30 seconds, followed by a purging cycle, to yield a homogenous SiAlOx layer approximately 25 nm thick.

### Resin Backfill

Following the ALD process, a protective acrylate coating (99:1 wt % ratio of SR833S to Irgacure 1173) was applied directly onto the SiAlOx ALD layer using a spin-coating process. The acrylate monomer was cured in a N₂-purged UV chamber to yield a protective polymer layer approximately 6.5 μm thick.

All references and publications cited herein are expressly incorporated herein by reference in their entirety into this disclosure. Illustrative embodiments of this invention are discussed and reference has been made to possible variations within the scope of this invention. For example, features depicted in connection with one illustrative embodiment may be used in connection with other embodiments of the invention. These and other variations and modifications in the invention will be apparent to those skilled in the art without departing from the scope of the invention, and it should be understood that this invention is not limited to the illustrative embodiments set forth herein. Accordingly, the invention is to be limited only by the claims provided below and equivalents thereof.

1. A film comprising:
a substrate;
a first barrier layer on the substrate;
a first resin layer on the first barrier layer;
wherein the first resin layer comprises a structured major surface and a plurality of features;
a second barrier layer on the structured major surface of the first resin layer; and
a second resin layer on the second barrier layer, wherein the second resin layer comprises a structured major surface and a plurality of features.

2. The film of claim 1, further comprising an adhesive layer on the second resin layer.

3. The film of claim 2, wherein the first or second resin layer has a first refractive index, the adhesive layer has a second refractive index and the second refractive index is different from the first refractive index.

4. The film of claim 2, wherein the first or second resin layer has a first refractive index, the adhesive layer has a second refractive index and the second refractive index is substantially the same as the first refractive index.

5. The film of claim 1, wherein the first resin layer comprises a second flat major surface opposite the structured major surface of the first resin layer.

6. The film of claim 1, wherein the second resin layer comprises a second flat major surface opposite the structured major surface of the second resin layer.

7. The film of claim 1, wherein a height of the plurality of features is between 5 μm and 50 μm.

8. The film of claim 1, wherein the plurality of features extend along a first direction.

9. The film of claim 1, wherein at least two of features extend along a non-parallel first direction.

10. The film of claim 1, wherein the plurality of features are substantially continuous along a second direction.

11. The film of claim 1, wherein the plurality of features are linear prisms extending along concentric circles, rectangles, squares, or other polygon shapes.

12. The film of claim 1, wherein the plurality of features are nanoscale features.

13. The film of claim 12, wherein the plurality of features are randomly arrayed features.

14. The film of claim 13, wherein the randomly arrayed features are randomly arrayed nanoscale features.

15. The film of claim 1, wherein the plurality of features are orderly arrayed features.

16. The film of claim 1, wherein the plurality of features comprise microscale features and nanoscale features.

17. The film of claim 16, wherein the plurality of features comprise ordered microscale features and randomly arrayed nanoscale features.

18. The film of claim 16, wherein the nanoscale features are formed on the microscale features.

19. An article, comprising:
the film of claim 1; and
an oxygen or moisture sensitive device.
